(19) United States
(12) Patent Application Publication
(10) Pub. No.: US 2026/0123157 A1
(43) Pub. Date: Apr. 30, 2026

(54) STRUCTURES FOR LIGHT-EMITTING DIODE PACKAGES WITH MULTIPLE LIGHT-EMITTING DIODE CHIPS

(71) Applicant: CreeLED, Inc., Durham, NC (US)

(72) Inventors: JuZuo Sheng, Huizhou (CN); Chak Hau Charles Pang, Hong Kong (CN); Yue Kwong Victor Lau, Hong Kong (CN); Zhenyu Zhong, Hong Kong (CN); Robert David Schmidt, Wake Forest, NC (US)

(21) Appl. No.: 18/726,556

(22) PCT Filed: Mar. 28, 2023
(86) PCT No.: PCT/CN2023/084513

§ 371 Date: Jul. 3, 2024

(51) Int. Cl. H10H 29/855

(52) U.S. Cl. CPC H10H 29/855

(57) ABSTRACT

Solid-state lighting devices including light-emitting diodes (LEDs) and more particularly structures for LED packages with multiple LED chips are disclosed. LED package structures include arrangements of one or more of body structures with multiple cavities for LED chips, encapsulants with lenses registered with the multiple cavities, and lead frame structures at least partially within the body structures. Cavities of body structures and/or corresponding lenses are disclosed with certain asymmetries configured to direct highest intensities of LED chip emissions in directions that are offset from cavity centers. Body structures are disclosed with one or more continuously planar surfaces that promote enhanced flexibility in encapsulant and/or lead frame structures and improved resistance to moisture ingress. One or more combinations of cavities and/or lenses asymmetries may be implemented in combination with one or more continuously planar body surfaces.

### FIELD OF THE DISCLOSURE

The present disclosure relates to solid-state lighting devices including light-emitting diodes (LEDs) and more particularly to structures for LED packages with multiple LED chips.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new display applications and are being increasingly utilized for general illumination applications, often replacing incandescent and fluorescent light sources.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from silicon carbide, gallium nitride, gallium phosphide, aluminum nitride, gallium arsenide-based materials, and/or from organic semiconductor materials. LED packages are solid-state devices that incorporate one or more LED chips into a packaged device. An LED chip may be enclosed in a component package to provide environmental and/or mechanical protection, light focusing and the like.

LEDs are now being used in displays, both big and small. Large or giant screen LED displays are becoming more common in many indoor and outdoor locations, such as at sporting events, concerts and in large public areas. Depending on the size, many of these displays can include thousands of “pixels” mounted on a flat surface to generate an image, with each pixel containing a plurality of LEDs. The pixels can use high efficiency and high brightness LEDs that allow the displays to be visible from relatively far away, even in the daytime when subject to sunlight. The pixels can have as few as three or four LEDs (one red, one green, and one blue) that allow the pixel to emit many different colors of light from combinations of red, green and/or blue light. In the largest screens, pixel modules may be arranged together to form the display where each pixel module can have three or more LEDs, with some having dozens of LEDs. Some large LED displays are arranged for wide angle or wide pitch emission that allows for a wide lateral range of viewing angles. Pixels for conventional LED displays can be formed of individual LED chips that are separately packaged and assembled in close proximity to one another, or each pixel can be formed of an LED package that includes multiple LED chips.

The art continues to seek improved LEDs and solid-state lighting devices having increased light output and increased light emission efficiencies without impairing manufacturability and reliability of such devices, while providing desirable illumination characteristics capable of overcoming challenges associated with conventional lighting devices.

### SUMMARY

The present disclosure relates to solid-state lighting devices including light-emitting diodes (LEDs) and more particularly to structures for LED packages with multiple LED chips. LED package structures include arrangements of one or more of body structures with multiple cavities for LED chips, encapsulants with lenses registered with the multiple cavities, and lead frame structures at least partially within the body structures. Cavities of body structures and/or corresponding lenses are disclosed with certain asymmetries configured to direct highest intensities of LED chip emissions in directions that are offset from cavity centers. Body structures are disclosed with one or more continuously planar surfaces that promote enhanced flexibility in encapsulant and/or lead frame structures and improved resistance to moisture ingress. One or more combinations of cavities and/or lenses asymmetries may be implemented in combination with one or more continuously planar body surfaces.

In one aspect, an LED package comprises: a body forming a plurality of cavities, a first cavity of the plurality of cavities forming a first cavity shape with no more than one line of symmetry; a plurality of LED chips, wherein each cavity of the plurality of cavities comprises at least one LED chip of the plurality of LED chips; and a plurality of lenses on the body, a first lens of the plurality of lenses being registered with the first cavity, and the first lens forming a first lens shape with no more than one line of symmetry. In certain embodiments, the first cavity comprises a sidewall that is arranged around a perimeter of the at least one LED chip within the first cavity, the sidewall forming a first sidewall portion and a second sidewall portion positioned on opposite sides of the at least one LED chip, wherein the second sidewall portion comprises a larger surface area of the cavity than the first sidewall portion. In certain embodiments: the at least one LED chip is mounted at a cavity floor of the first cavity; a first angle is formed from the first sidewall portion relative to a perpendicular line from the cavity floor; a second angle is formed between the second sidewall portion relative to the perpendicular line from the cavity floor; and the first angle is less than the second angle. In certain embodiments, the first angle is in a range from 5 degrees to 25 degrees and the second angle is in a range from 25 degrees to 50 degrees. In certain embodiments, the first angle is in a range from 10 degrees to 20 degrees and the second angle is in a range from 30 degrees to 40 degrees. In certain embodiments, the sidewall is continuously curved around the perimeter of the at least one LED chip.

In certain embodiments, each cavity of the plurality of cavities comprises a cavity shape that is the same as the first cavity shape, and each lens of the plurality of lenses comprises a lens shape that is the same as the first lens shape. In certain embodiments: the body forms a rectangular shape with a long side and a short side; the plurality of cavities are arranged in a linear manner in a direction corresponding to the long side; and the first cavity forms a single line of symmetry that is oriented parallel to the long side. In certain embodiments, the plurality of cavities further comprises a second cavity forming a second cavity shape with no more than one line of symmetry and a third cavity forming a third cavity shape with no more than one line of symmetry. The LED package may further comprise a lead frame structure at least partially within the body and electrically coupled to the plurality of LED chips.

In certain embodiments: the body comprises a top face, a bottom face, and side faces that bound the top face and the bottom face; the plurality of cavities are in the top face of the body; and the top face is continuously planar between opposing side faces. In certain embodiments, the side faces are continuously planar between the top face and the bottom face.

In another aspect, an LED package comprises: a first LED chip and a second LED chip; and a body comprising: a first cavity with a first cavity floor on which the first LED chip resides and a first sidewall that extends between a surface of the body and the first cavity floor, wherein an angle of the first sidewall relative to the first cavity floor varies around a perimeter of the first LED chip; and a second cavity with a second cavity floor on which the second LED chip resides and a second sidewall that extends between the surface of the body and the second cavity floor, wherein an angle of the second sidewall relative to the second cavity floor varies around a perimeter of the second LED chip. In certain embodiments: the angle of the first sidewall is in a range from 5 degrees to 25 degrees on one side of the first LED chip and in a range from 25 degrees to 50 degrees on an opposing side of the first LED chip; and the angle of the second sidewall is in a range from 5 degrees to 25 degrees on one side of the second LED chip and in a range from 25 degrees to 50 degrees on an opposing side of the second LED chip. In certain embodiments: the angle of the first sidewall is in a range from 10 degrees to 20 degrees on one side of the first LED chip and in a range from 30 degrees to 40 degrees on an opposing side of the first LED chip; and the angle of the second sidewall is in a range from 10 degrees to 20 degrees on one side of the second LED chip and in a range from 30 degrees to 40 degrees on an opposing side of the second LED chip.

The LED package may further comprise a lead frame structure at least partially within the body and electrically coupled to the first LED chip and the second LED chip. The LED package may further comprise a first lens that is registered with the first cavity and a second lens that is registered with the second cavity, wherein each of the first lens and the second lens forms a shape with no more than one line of symmetry. The LED package may further comprise a third LED chip and a third cavity with a third cavity floor on which the third LED chip resides and a third sidewall that extends between the surface of the body and the third cavity floor, wherein an angle of the third sidewall relative to the third cavity floor varies around a perimeter of the third LED chip. In certain embodiments, the first LED chip is positioned offset from a center point of the first cavity floor, and the second LED chip is positioned offset from a center point of the second cavity floor. In certain embodiments, the first LED chip is positioned offset from a center point of the first cavity floor, and the second LED chip is positioned at a center point of the second cavity floor.

In certain embodiments: the body comprises a top face, a bottom face, and side faces that bound the top face and the bottom face; the first cavity and the second cavity are in the top face of the body; and the top face is continuously planar between opposing side faces. In certain embodiments the side faces are continuously planar between the top face and the bottom face.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a top perspective view of a light-emitting diode (LED) package according to embodiments disclosed herein.

FIG. 1B is a top perspective view of the LED package of FIG. 1A with the addition of an encapsulant.

FIG. 1C is a top view of the LED package of FIG. 1A with the addition of an LED chip within each of the cavities.

FIG. 1D is a top view of a portion of the LED package of FIG. 1C that includes the cavity.

FIG. 1E is a partial cross-sectional view of the LED package of FIG. 1D illustrating differences in sidewall angles.

FIG. 1F is a side view of the LED package of FIG. 1C with the addition of the encapsulant and lenses.

FIG. 2 is a top view of an LED package that is similar to the LED package of FIG. 1C except the LED chips in each of the cavities are positioned closer to the first sidewall portions than the second sidewall portions.

FIG. 3 is a top view of an LED package that is similar to the LED package of FIG. 2 except the LED chips in each of the cavities are positioned closer to the second sidewall portions than the first sidewall portions.

FIG. 4 is a top view of an LED package that is similar to the LED package of FIG. 2 except the LED chips in each of the cavities are variably positioned relative to the second sidewall portions than the first sidewall portions.

FIG. 5 is a top view of an LED package that is similar to the LED package of FIG. 1C with an alternative arrangement of the leads.

FIG. 6A is a top perspective view of an LED package that is similar to the LED package of FIG. 1A for embodiments that do not include the body mesa of FIG. 1A.

FIG. 6B is a top view of the LED package of FIG. 6A with the addition of an LED chip within each of the cavities.

FIG. 6C is a bottom view of the LED package of FIG. 6B.

FIG. 6D is an end view of the LED package of FIG. 6B along a short side or width of the LED package.

FIG. 6E is a side view of the LED package of FIG. 6B along a long side or length of the LED package.

FIG. 7 is a top perspective view of the LED package of FIG. 6A with the addition of the encapsulant along the top face of the body.

FIG. 8 is a top perspective view of an LED package that is similar to the LED package of FIG. 7 with a reduced thickness flash portion of the encapsulant.

FIG. 9 is a top perspective view of an LED package that is similar to the LED package of FIG. 8 except the flash portion of FIG. 8 is omitted.

FIG. 10 is a top perspective view of an LED package that is similar to the LED package of FIG. 7 with lens shapes similar to the LED package of FIGS. 1B and 1F.

FIG. 11 is a top perspective view of an LED package that is similar to the LED package of FIG. 10 with the flash portion similar to the LED package of FIG. 8.

FIG. 12 is a top perspective view of an LED package that is similar to the LED package of FIG. 11 with the flash portion of FIG. 11 omitted in a similar to the LED package of FIG. 9.

FIG. 13A is a top perspective view of an LED package that is similar to the LED package of FIG. 6A for embodiments where the side faces are continuously planar from the top face to the bottom face of the body.

FIG. 13B is a top view of the LED package of FIG. 13A with the addition of the LED chip within each of the cavities.

FIG. 13C is a bottom view of the LED package of FIG. 13B.

FIG. 13D is an end view of the LED package of FIG. 13B along a short side or width of the LED package.

FIG. 13E is an end view of the LED package of FIG. 13B that is similar to FIG. 13D with the body represented as semi-transparent.

FIG. 13F is a side view of the LED package of FIG. 13B along a long side or length of the LED package.

FIG. 14 is a top perspective view of the LED package of FIG. 13A with the addition of the encapsulant along the top face of the body.

FIG. 15 is a top perspective view of an LED package that is similar to the LED package of FIG. 14 with a reduced thickness flash portion of the encapsulant.

FIG. 16 is a top perspective view of an LED package that is similar to the LED package of FIG. 15 except the flash portion of FIG. 15 is omitted.

FIG. 17 is a top perspective view of an LED package that is similar to the LED package of FIG. 14 with lens shapes similar to the LED package of FIG. 10.

FIG. 18 is a top perspective view of an LED package that is similar to the LED package of FIG. 17 with the flash portion similar to the LED package of FIG. 15.

FIG. 19 is a top perspective view of an LED package that is similar to the LED package of FIG. 18 except the flash portion of FIG. 18 is omitted.

FIG. 20A is a top perspective view of an LED package that is similar to the LED package of FIGS. 13A to 13F and further includes the body mesa of the LED package of FIGS. 1A to 1F.

FIG. 20B is a top view of the LED package of FIG. 20A with the addition of the LED chip within each of the cavities.

FIG. 20C is a bottom view of the LED package of FIG. 20B.

FIG. 20D is an end view of the LED package of FIG. 20B along a short side or width of the LED package.

FIG. 20E is an end view of the LED package of FIG. 20B that is similar to FIG. 20D with the body represented as semi-transparent.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to solid-state lighting devices including light-emitting diodes (LEDs) and more particularly to structures for LED packages with lead frames. LED packages include lead frame structures at least partially enclosed by body structures, or housings. Arrangements for LED packages are disclosed that provide improved light shaping for desired emission directions, and improved reliability for a variety of lighting applications, including outdoor LED displays as well as general illumination. In certain embodiments, LED packages include arrangements of LED chips within cavities of a body structure and corresponding lenses. Structures of the cavities, lenses, or combinations thereof are disclosed that provide improved light shaping. Further arrangements of body structures relative to lead frame structures are disclosed that provide improved adhesion with encapsulant materials and optional potting materials to provide improved moisture barriers.

An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure can comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, un-doped layers, cladding layers, contact layers, and current-spreading layers and light extraction layers and elements. The active layer can comprise a single quantum well, a multiple quantum well, a double heterostructure, or super lattice structures.

The active LED structure can be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). For Group III nitrides, silicon (Si) is a common n-type dopant and magnesium (Mg) is a common p-type dopant. Accordingly, the active layer, n-type layer, and p-type layer may include one or more layers of GaN, AlGaN, InGaN, and AlInGaN that are either undoped or doped with Si or Mg for a material system based on Group III nitrides. Other material systems include silicon carbide (SiC), organic semiconductor materials, and other Group III-V systems such as gallium phosphide (GaP), gallium arsenide (GaAs), and related compounds.

Different embodiments of the active LED structure can emit different wavelengths of light depending on the composition of the active layer and n-type and p-type layers. In certain embodiments, the active LED structure emits blue light with a peak wavelength range of approximately 430 nanometers (nm) to 480 nm. In other embodiments, the active LED structure emits green light with a peak wavelength range of 500 nm to 570 nm. In other embodiments, the active LED structure emits red light with a peak wavelength range of 600 nm to 650 nm. In certain embodiments, a multiple-chip LED package for use as a pixel in a display may include at least one blue-emitting LED chip, at least one green-emitting LED chip, and at least one red-emitting LED chip.

LED chips within packages may also be covered with one or more lumiphoric or other conversion materials, such as phosphors, such that at least some of the light from the LED chip is absorbed by the one or more phosphors and is converted to one or more different wavelength spectra according to the characteristic emission from the one or more phosphors. For example, the combination of a blue-emitting LED chip and one or more phosphors may be configured to provide a generally white combination of light. The one or more phosphors may include yellow (e.g., YAG: Ce), green (e.g., LuAg: Ce), and red (e.g., Cai-x-ySrxEuyAlSiN3) emitting phosphors, and combinations thereof. Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like).

Light emitted by the active layer or region of an LED chip is typically omnidirectional in nature. For directional applications, internal mirrors or external reflective surfaces of LED packages may be employed to redirect as much light as possible toward a desired emission direction. As used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In the case of ultraviolet (UV) LEDs, appropriate materials may be selected to provide a desired, and in some embodiments high, reflectivity and/or a desired, and in some embodiments low, absorption.

The present disclosure can be useful for LED chips having a variety of geometries, such as vertical geometry or lateral geometry. A vertical geometry LED chip typically includes anode and cathode connections on opposing sides or faces of the LED chip. A lateral geometry LED chip typically includes both anode and cathode connections on the same side of the LED chip that is opposite a substrate, such as a growth substrate. In certain embodiments, one or more wire bonds may be used to provide electrical connections between anode and cathode connections and lead frame structures of LED package. In other arrangements, some LED chips may be flip-chip mounted and electrically coupled to the lead frame structure without the use of wire bonds.

The present disclosure is directed to various embodiments of surface mount device (SMD) LED packages and LED displays using such packages. Each of the LED packages may be arranged to be used as a single pixel, instead of conventional LED displays where multiple LED packages are used to form each pixel. This may provide easier and less expensive manufacturing of LED displays, improved reliability for LED displays, and in some instances, may result in a higher density or resolution display with an increased pixel count for a given display area. In certain embodiments, LED packages according to the present disclosure may have one or more round or oval shaped cavities. The cavities can have corresponding round or oval shaped lens formed thereon for shaping or tailoring the overall emission of the LED packages. Oval shaped lenses may provide wide angle or wide pitch emission along an axis or centerline of the LED package or the oval shaped lens. This allows LED displays that are configured for wider viewing angles. In certain embodiments, a particular LED package may have combinations of oval and round shaped cavities with corresponding oval and round shaped lenses.

In addition to the above advantages, LED packages according to the present disclosure can be easier to handle compared to conventional LED lamps used to form pixels for LED displays and can be easier to assemble into LED displays. The LED packages and resulting LED displays can provide improved emission characteristics while at the same time being more reliable and providing longer life spans.

The different embodiments according to the present disclosure can comprise different shapes and sizes of cavities, with some cavities having a curved surface while others can have angled sidewalls and planar base. Depending on the desired emission direction, LED chips may be mounted proximate center positions at cavity floors or in positions offset from center. Lenses may be provided over each of the cavities. In certain aspects, lens shapes are disclosed that are configured to angle light in desired directions in combination with various cavity shapes. For example, aspects as disclosed herein may be well suited to increase downward emissions for LED packages in high-view LED displays, such displays in stadiums, arenas, roadways, billboards, or on sides of buildings. In certain embodiments, the LED chips within a package may emit multiple colors, such as red, green and blue, and the LED chips may be individually controllable to emit different color combinations and intensities of light. The LED chips may be arranged in close proximity to one another within a corresponding LED package to approximate a point light source for enhanced color mixing and uniformity within the far field emission pattern.

Certain aspects relate to LED packages with various structures for enhanced operational reliability. Body structure arrangements are disclosed with various features that enhance formation and/or adhesion of overlying lenses. Further body structure arrangements include features that provide improved bonding with potting materials used with mounting of LED packages and/or reduced moisture intrusion. In still further embodiments, one or more combinations of the cavity structures, lens structures, and body structures may be used together to provide LED packages with enhanced emission characteristics and improved reliability.

The present disclosure is described herein with reference to certain embodiments, but it is understood that the disclosure can be embodied in many different forms and should not be construed as limited to the embodiments set forth herein. In particular, many different LED reflective cup and lead frame arrangements can be provided beyond those described herein, and the encapsulant can provide further features to alter the direction of emissions from the LED packages and LED displays utilizing the LED packages. Although the different embodiments of LED packages discussed below are directed to use in LED displays, they can be used in many other applications either individually or with other LED packages having the same or different peak emission tilt.

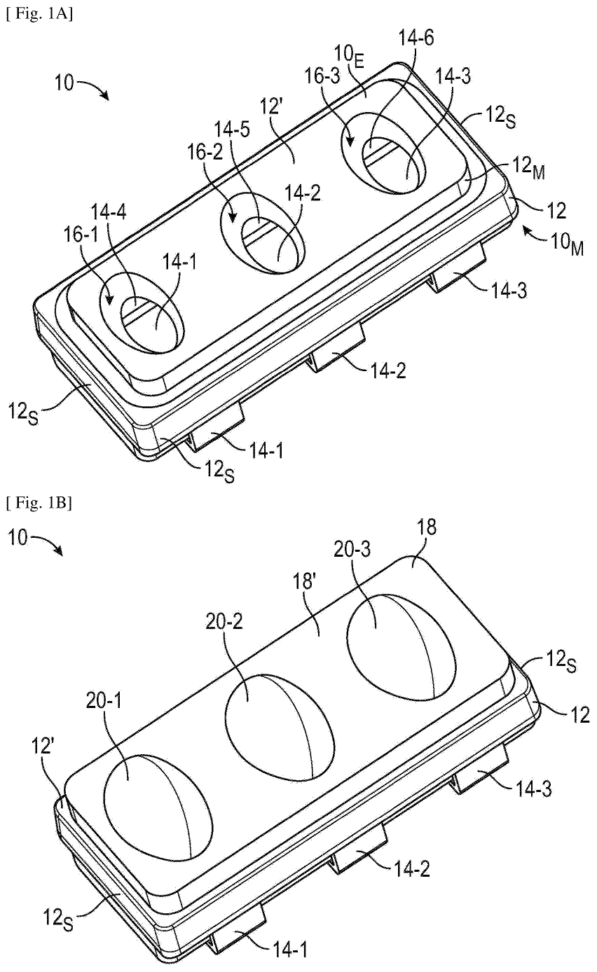

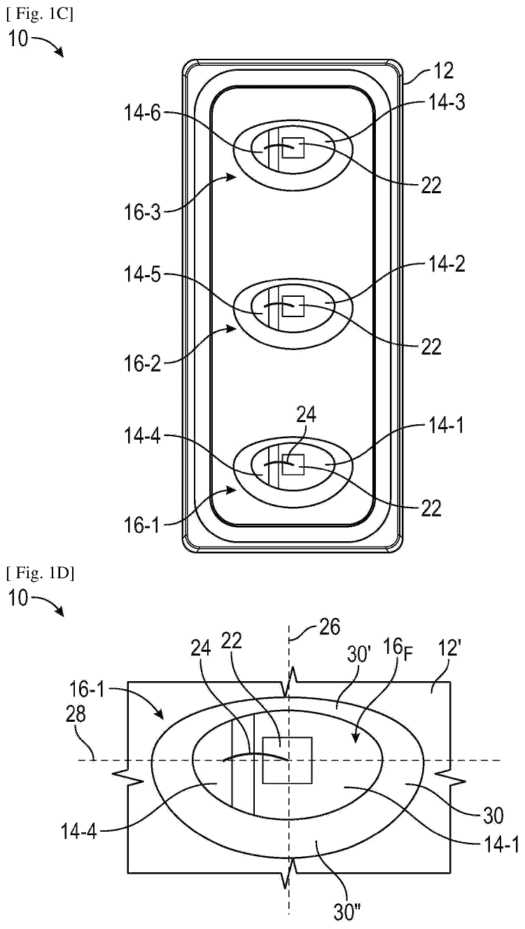

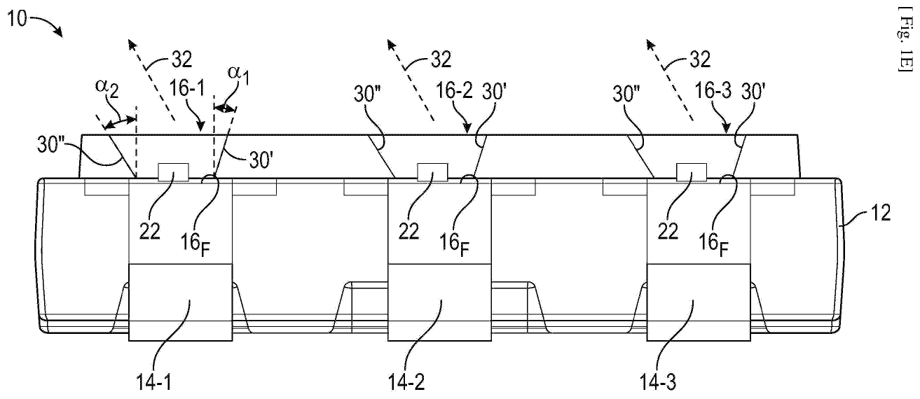

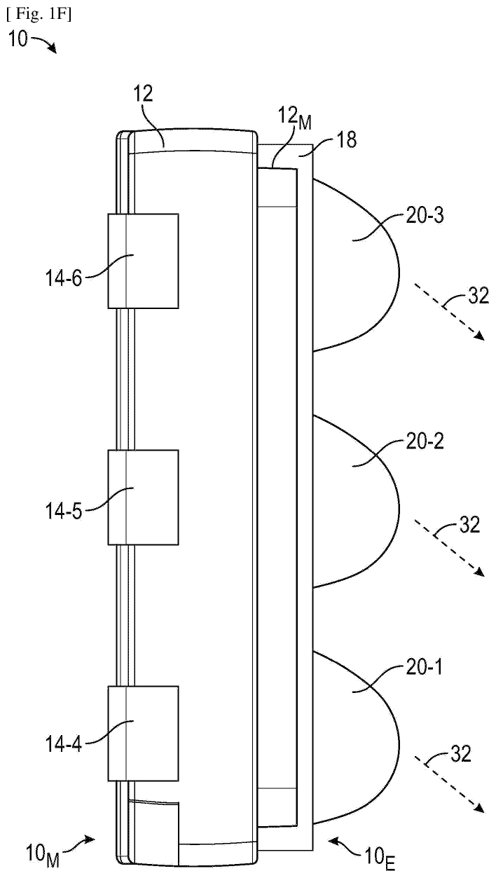

FIG. 1A is a top perspective view of an LED package 10 according to embodiments disclosed herein. The LED package 10 includes a body 12, or body structure, that is arranged at least partially around a lead frame structure that includes leads 14-1 to 14-6. In certain embodiments, the body 12 includes an insulating material that is formed around and between portions of the leads 14-1 to 14-6 to provide mechanical stability as well as electrical insulation. The body 12 may comprise a molded plastic material or a ceramic material, among others. As illustrated, a top face 12′ of the body 12 forms part of a primary emission face 10_{E} of the LED package 10 and part of a mounting face 10_{M} for the LED package 10 that opposes the primary emission face 10_{E}. The primary emission face 10_{E} and the mounting face 10_{M} are peripherally bounded by side faces 12_{S} of the body 12. The leads 14-1 to 14-6 are typically structures formed of an electrically conductive metal, such as copper, copper alloys, or other conductive metals. The leads 14-1 to 14-6 may initially be part of a larger lead frame structure that is singulated during manufacturing to form individual LED packages. During fabrication, a separate body 12 may be formed in each area of a lead frame structure where an individual LED package will be formed after singulation.

In the LED package 10, the leads 14-1 to 14-6 are arranged to extend out of the body 12 at or along one or more of the side faces 12_{S}. In certain embodiments, the leads 14-1 to 14-6 are arranged to bend along the side faces 12_{S} and then bend along the mounting face 10_{M}. In this manner, portions of the leads 14-1 to 14-6 are arranged on the mounting face 10_{M} in order to make electrical connections to an external source when mounted. For example, the LED package 10 may be mounted on a printed circuit board with electrical traces that correspond to the leads 14-1 to 14-6. The body 12 may further include a body mesa 12_{M} that is formed at the primary emission face 10_{E}. As illustrated, the body mesa 12_{M} is arranged as a protrusion of the body 12 at the primary emission face 10_{E}. In certain embodiments, the body mesa 12_{M} is inset from the side faces 12_{S} of the body 12 to form a step structure along a perimeter at the top of the body 12. The body mesa 12_{M} includes sidewalls that protrude along the primary emission face 10_{E}. In certain embodiments, the body mesa 12_{M} forms a plurality of cavities 16-1 to 16-3 at the primary emission face 10_{E}. The plurality of cavities 16-1 to 16-3 form cups or recesses in which LED chips are mounted within the LED package 10. As such the cavities 16-1 to 16-3 form openings in the body that provide access to a different pair of lead frames, e.g. the leads 14-1, 14-4 for the cavity 16-1; the leads 14-2, 14-5 for the cavity 16-2; and the leads 14-3, 14-6 for the cavity 16-3.

FIG. 1B is a top perspective view of the LED package 10 of FIG. 1A with the addition of an encapsulant 18. The encapsulant 18 may comprise a material such as silicone or epoxy that is arranged to fill and thereby encapsulate each of the cavities (e.g., 16-1 to 16-3 of FIG. 1B) and LED chips that are mounted therein. In certain embodiments, the encapsulant 18 may be light-transmissive or light-transparent to light emitted by the LED chips. In certain embodiments, the encapsulant 18 may comprise a conversion material or scattering material arranged throughout or arranged in different locations in the encapsulant 18. As illustrated, the encapsulant 18 forms a plurality of lenses 20-1 to 20-3 such that a separate lens 20-1 to 20-3 is registered with a separate one of the cavities 16-1 to 16-3. In this manner, the plurality of lenses 20-1 to 20-3 are configured to focus, alter, or otherwise tailor the emission pattern of light generated by each of the LED chips. In certain embodiments, the lenses 20-1 to 20-3 form a shape that is circular, although other shapes are contemplated depending on the desired emission pattern. Some examples of alternative shapes include oval, ellipsoid bullet, flat, hex-shaped, and square. As will be described later in greater detail, the lenses 20-1 to 20-3 may be formed with a shape where a focal point of the lenses 20-1 to 20-3 is offset from centers of the cavities 16-1 to 16-3 to direct light in desired emission directions. The encapsulant 18 and the lenses 20-1 to 20-3 may be formed over the body 12 using different known molding processes. In certain embodiments, the encapsulant 18 may be formed to extend along the top face 12′ of the body 12 such that the encapsulant 18 extends beyond peripheral boundaries of the body mesa 12_{M}. In this manner, improved adhesion may be provided between the encapsulant 18 and the body 12. In certain embodiments, the encapsulant 18 is continuous between each of the lenses 20-1 to 20-3 and along portions of the top face 12′. Such portions of the encapsulant 18 that extend between the lenses 20-1 to 20-3, along the body mesa 12_{M}, and along the top face 12′ may be referred to as a flash portion 18′ of the encapsulant 18.

FIG. 1C is a top view of the LED package 10 of FIG. 1A with the addition of an LED chip 22 within each of the cavities 16-1 to 16-3. For illustrative purposes, each of the LED chip 22 is represented with a vertical chip structure where one side of the LED chip 22 is mounted and electrically coupled to one lead (e.g., 14-1 for the cavity 16-1) and electrically coupled to the other lead (e.g., 14-4 for the cavity 16-1) by way of a wire bond. In other embodiments electrical connections to each lead frame pair may be made by wire bonds. In still further embodiments, one or more of the LED chips 22 may be flip-chip mounted to a corresponding lead frame pair without the use of a wire bond. In any case, electrical connections between the leads 14-1 to 14-6 and the LED chips 22 may be configured such that each of the LED chip 22 is individually addressable and capable of being electrically activated independently. This allows an LED display to incorporate an array of the LED packages 10, where each LED package 10 provides a pixel of the LED display. As further illustrated in FIG. 1C, the cavities 16-1 to 16-3 may be arranged in a linear manner within the body 12 to promote uniform spacing and arrangement of the LED chips 22 across multiple LED packages 10 when arranged in a display. The linear arrangement may further provide improved color mixing and higher visibility at various viewing angles as described below.

FIG. 1D is a top view of a portion of the LED package 10 of FIG. 1C that includes the cavity 16-1. The shapes described below for the cavity 16-1 may also be implemented for one or more of the cavities 16-2 and 16-3 of FIG. 1D. In still further embodiments, any one or more of the cavities 16-1 to 16-3 of FIG. 1D may have the shapes described below while others of the cavities 16-1 to 16-3 may have generally symmetric shapes.

As illustrated in FIG. 1D, the cavity 16-1 is generally asymmetric to direct increased emissions in an offset manner, in this case downward relative to the LED package 10. For example, superimposed dashed lines in FIG. 1D illustrate a vertical center line 26 and a horizontal center line 28 of the cavity 16-1 that is perpendicular to the vertical center line 26. As illustrated, the cavity 16-1, including a cavity floor 16_{F} and at least one sidewall 30, may form a generally asymmetric cavity shape with no more than one line of symmetry relative to the opening formed by the cavity 16-1 in the body 12. For example, the opening of the cavity 16-1 at the top face 12′ of the body 12 may have symmetry about only the vertical center line 26 such that no other lines of symmetry are present. By having a single line of symmetry along the vertical center line 26, the package emissions may be generally uniform from left and right viewing positions while maintaining a shift in downward emissions attributed to the remaining asymmetry of the cavity 16-1. The cavity 16-1 includes the at least one sidewall 30 that extends between the cavity floor 16_{F} where the LED chip 22 is mounted and a surface of the body 12 that is outside the cavity 16-1. The sidewall 30 may extend in a continuously curved manner around the cavity floor 16_{F}. The cavity floor 16_{F} forms a mounting surface for the LED chip 22 where one or more portions of the leads 14-1 and 14-4 are accessible relative to the body 12. A first sidewall portion 30′ generally corresponds with a portion of the sidewall 30 that may be positioned above a second sidewall portion 30″ when the LED package 10 is oriented as illustrated in FIG. 1C. In this manner, the first sidewall portion 30′ and the second sidewall portion 30″ are positioned on opposing sides of the LED chip 22. From the top view of FIG. 1D, the second sidewall portion 30″ has a larger surface area of the cavity 16-1 than the first side wall portion 30′. This is due in part to the second sidewall portion 30″ having a wider angle between the cavity floor 16_{F} and the body 12 than a corresponding angle of the first sidewall portion 30′.

When the LED package 10 is arranged vertically such that the second sidewall portion 30″ is positioned lower than the first sidewall portion 30′, increased light from the LED chip 22 may emit downwards from the cavity 16-1. In the context of FIG. 1C, when the cavities 16-1 to 16-3 with such shapes are arranged in a linear manner within the LED package 10, second sidewall portions 30″ of each cavity 16-1 to 16-3 are oriented in a same downward direction. As further illustrated in FIG. 1C, the LED package 10 and body 12 have an overall rectangular shape such that the cavities 16-1 to 16-3 are linearly arranged in a direction corresponding to a long side, or length, of the rectangular shape and the second sidewall portions 30″ are positioned to direct increased downward emissions toward a short side, or width, of the rectangular shape. In this manner, the vertical center line 26 of FIG. 1D, which may represent the only line of symmetry for the cavity 16-1, may be oriented parallel to the long side of the rectangular shape of the body 12 in FIG. 1C.

FIG. 1E is a partial cross-sectional view of the LED package 10 of FIG. 1D illustrating differences in sidewall angles. For illustrative purposes superimposed dashed lines are provided relate to the cavity 16-1. However, it is understood one or both of the other cavities 16-2, 16-3 may also have the same sidewall angles. As illustrated, a first angle α₁ is formed from the first sidewall portion 30′ relative to a perpendicular line from the cavity floor 16_{F}, and a second angle α₂ is formed from the second sidewall portion 30″ relative to a perpendicular line from the cavity floor 16_{F}. The first angle α₁ is less than the second angle α₂ relative to the perpendicular lines from the cavity floor 16_{F}, indicating a steeper slope for the first sidewall portion 30′. In this manner increased light from the LED chip 22 will be angled in a direction towards the second sidewall portion 30″ such that emissions of highest intensity 32 from the LED chips 22 are offset from perpendicular to the cavity floor 16_{F}. Accordingly, the sidewall angles of the cavities 16-1 to 16-3 relative to the cavity floor 16_{F} may vary around a perimeter of the LED chip 22. In certain embodiments, the first angle α₁ is provided in a range from 5 degrees to 25 degrees or in a range from 10 degrees to 20 degrees, and the second angle α₂ is provided in a range from 25 to 50 degrees or in a range from 30 to 40 degrees, particularly for high-view LED display applications.

FIG. 1F is a side view of the LED package 10 of FIG. 1C with the addition of the encapsulant 18 and lenses 20-1 to 20-3. In certain embodiments, the lenses 20-1 to 20-3 have shapes that are tilted downward to further promote increased downward emissions of light. For illustrative purposes, superimposed dashed-line arrows are provided to illustrate directions of emissions of the highest intensity 32 exiting each of the lenses 20-1 to 20-3. For a conventional hemispheric lens, a highest emission intensity is typically produced at a 90 degree angle relative to the mounting face 10_{M} of the LED package 10. By tilting the lenses 20-1 to 20-3, highest intensity emissions of the emission pattern may be angled in an offset manner, such as downward for high-view LED displays. The tilted lenses 20-1 to 20-3 may be used in combination with the shapes of the cavities 16-1 to 16-3 described above for FIGS. 1D and 1E to further enhance downward emissions. In certain embodiments, the tilted lenses 20-1 to 20-3 may each have shapes that correspond with the shapes of their respective underlying cavities 16-1 to 16-3. In this regard, one or more of the lenses 20-1 to 20-3 may be formed with a lens shape having no more than one line of symmetry.

In addition to the cavity and lens descriptions provided above for FIGS. 1A to 1F, positions of the LED chips 22 within the cavities 16-1 to 16-3 may further be arranged to tailor emission patterns of LED packages. In FIG. 1D, the LED chip 22 is positioned at a center of the cavity floor 16_{F} at an intersection of the vertical center line 26 and the horizontal center line 28. FIGS. 2 to 4 represent top views of LED packages that are similar to the LED package 10 of FIGS. 1A to 1F with various arrangements of the LED chips 22 that further tailor emission patterns.

FIG. 2 is a top view of an LED package 34 that is similar to the LED package 10 of FIG. 1C except the LED chips 22 in each of the cavities are positioned closer to the first sidewall portions 30′ than the second sidewall portions 30″. In this regard, light from the LED chips 22 will have less distance to travel the first sidewall portions 30′ before being redirected along the downward emission direction. With such a configuration, the LED package 34 may direct highest intensities of light in a more downward direction compared to a same LED package with centered LED chips 22. In this manner, the LED package 34 may be well suited for LED displayed positioned well above eye level of observers. The offset positions of the LED chips 22 relative to center points of the cavities may be implemented in combination with the cavity shape and the lens shape described above for FIGS. 1A to 1F.

FIG. 3 is a top view of an LED package 36 that is similar to the LED package 34 of FIG. 2 except the LED chips 22 in each of the cavities are positioned closer to the second sidewall portions 30″ than the first sidewall portions 30′. Such positioning may be provided to tailor amounts of downward emissions without having to change other parts of the LED package 36. For example, the LED package 34 of FIG. 2 may provide higher amounts of downward emissions compared to the LED package 36. While the LED package 36 may still be configured to provide highest intensities of light in the downward direction, shifting the LED chips 22 closer to the second sidewall portions 30″ may increase relative portions of the emission pattern normal to the LED chips 22 or even in an upward direction. Such an arrangement may be implemented for LED displays that are still above eye level of observers, but not necessarily as high as applications for the LED package 34 of FIG. 2. The positions of the LED chips 22 in the cavities 16-1 to 16-3 may be implemented in combination with the cavity shape and the lens shape described above for FIGS. 1A to 1F.

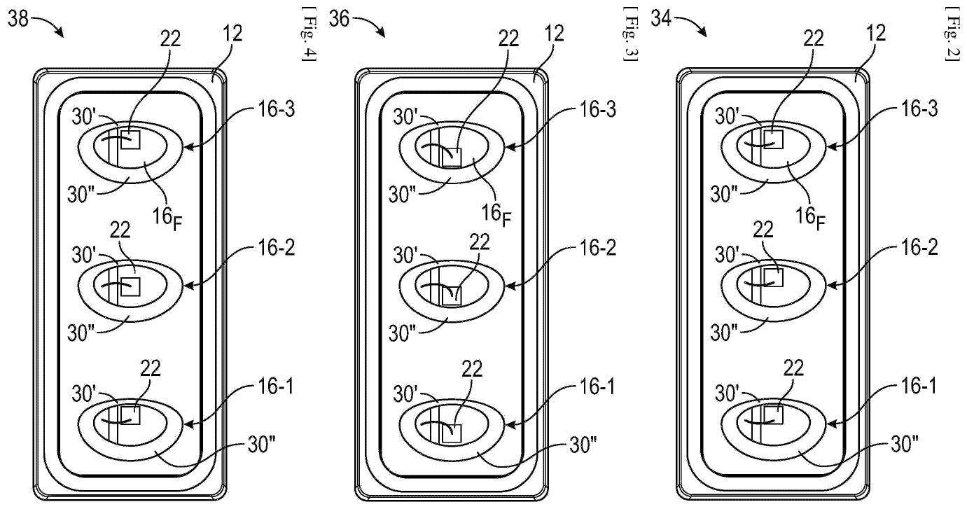

FIG. 4 is a top view of an LED package 38 that is similar to the LED package 34 of FIG. 2 except the LED chips 22 in each of the cavities are variably positioned relative to the second sidewall portions 30″ than the first sidewall portions 30′. For example the LED chips 22 in the cavities 16-1 and 16-3 are positioned closer to the first sidewall portions 30′ than the second sidewall portions 30″ while the LED chip 22 in the cavity 16-2 is positioned at a center point of the cavity floor 16_{F}.

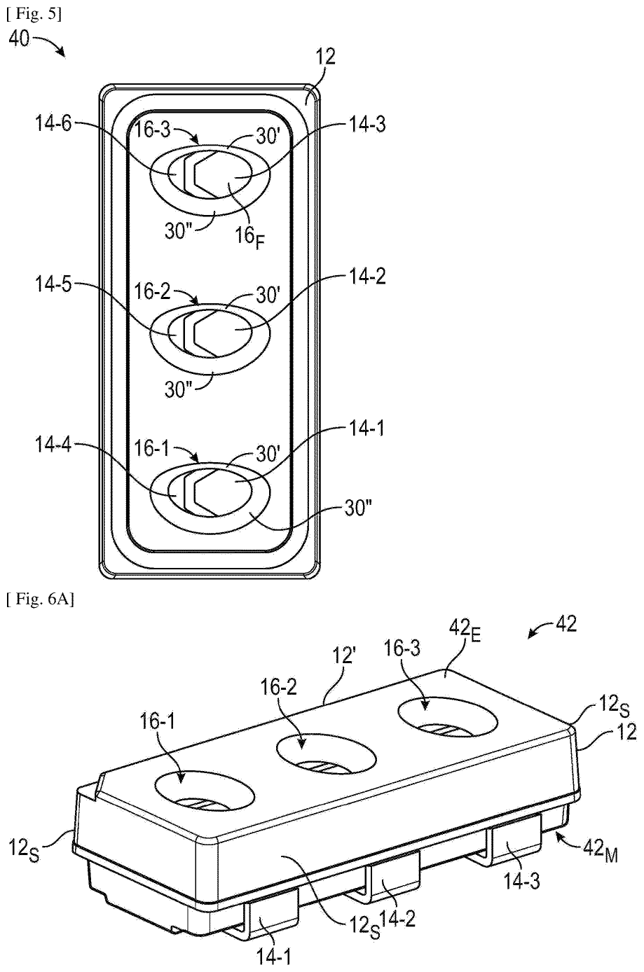

FIG. 5 is a top view of an LED package 34 that is similar to the LED package 10 of FIG. 1C with an alternative arrangement of the leads 14-1 to 14-6. In certain embodiments, the shape of the leads 14-1 to 14-6 relative to the asymmetry of the cavities 16-1 to 16-3 may be modified. As illustrated, each cavity 16-1 to 16-3 includes the cavity floor 16_{F} where a different pair of the leads 14-1 to 14-6 are accessible for LED chip connections. Within the cavity 16-1, the lead 14-1 is formed with a protruding shape proximate the center of the cavity 16-1 and the lead 14-4 has a bend shape that follows the protrusion of the lead 14-1. In this manner, a gap between the leads 14-1 and 14-4 may extend from the first sidewall portion 30′ to the second sidewall portion 30″ in a nonlinear manner. Such an arrangement may enable a variety of LED chip positions, such as those illustrated in any of FIGS. 1C to 1D and FIGS. 2 to 4. Additionally, such an arrangement may also provide enhanced adhesion between the body 12 and the leads 14-1 to 14-6 while accommodating the LED chip positions relative to the asymmetry of the cavities 16-1 to 16-3 described above.

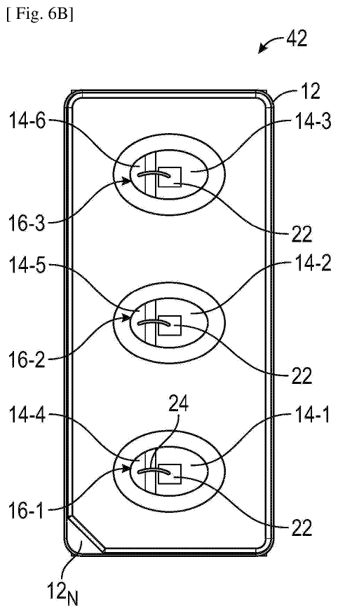

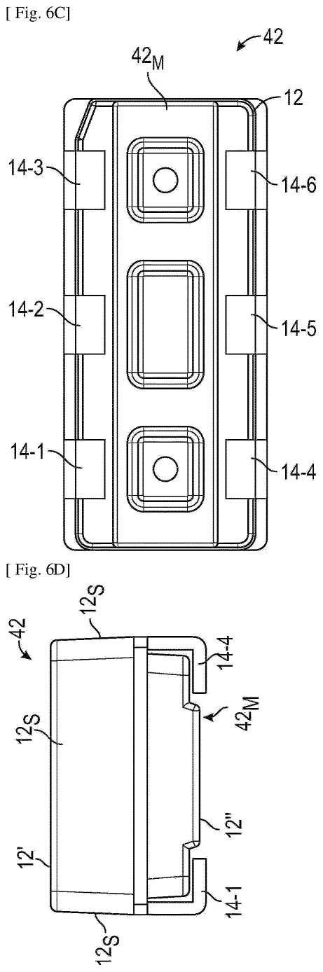

LED packages as disclosed herein may include further arrangements of the body, the lead frame structure, the encapsulant and/or lenses, and combinations thereof that provide enhanced mechanical and/or optical characteristics. Shapes of body structures relative to lead frame structures and/or encapsulant layers may provide improved manufacturability and/or improved environmental protection by providing more difficult water ingress pathways. Additional body and lead frame structure arrangements may reduce amounts of potting material needed when such LED packages are mounted for use. Any of the following arrangements of the body, the lead frame structure, the encapsulant and/or lenses, and combinations thereof described below for FIGS. 6A to 20E may be used alone or in combination with the shapes of the cavities, the lenses, lead frames, and/or positions of LED chips within cavities as described above for FIGS. 1A to 5.

FIG. 6A is a top perspective view of an LED package 42 that is similar to the LED package 10 of FIG. 1A for embodiments that do not include the body mesa 12_{M} of FIG. 1A. Without such a body mesa at the top face 12′ and or an emission surface 42_{E}, the body 12 is substantially planar across larger areas of the top face 12′. In certain embodiments, the body 12 is continuously planar between opposing side faces 12_{S} of the body 12 that define long sides, or a length of the body 12. Additionally, the body 12 is continuously planar between opposing side faces 12_{S} of the body 12 that define short sides, or a width of the body 12. As illustrated the various boundaries of the body 12 along the length and width may have curved corners that bound the continuously planar top face 12′ at the side faces 12_{S}. As will be described below in greater detail, the substantially planar top face 12′ may allow flexibility in shapes of other package elements, such as encapsulants and/or lenses.

FIG. 6B is a top view of the LED package 42 of FIG. 6A with the addition of the LED chip 22 within each of the cavities 16-1 to 16-3. For illustrative purposes, each LED chip 22 is represented with a vertical chip structure where one side of the LED chip 22 is mounted and electrically coupled to one lead (e.g., 14-1 for the cavity 16-1) and electrically coupled to the other lead (e.g., 14-4 for the cavity 16-1) by way of a wire bond. In other embodiments electrical connections to each lead frame pair may be made by wire bonds. In still further embodiments, one or more of the LED chips 22 may be flip-chip mounted to a corresponding lead frame pair without the use of a wire bond. In any case, electrical connections between the leads 14-1 to 14-6 and the LED chips 22 may be configured such that each of the LED chip 22 is individually addressable and capable of being electrically activated independently. For illustrative purposes, each of the cavities 16-1 to 16-3 are illustrated with generally oval shapes, however it is understood the cavities 16-1 to 16-3 may include the asymmetric shapes formed by the variably angled sidewalls as described above for FIGS. 1A to 1F. Additionally, the LED chips 22 may be positioned within the cavities 16-1 to 16-3 as described above for any of FIGS. 1D-1F and FIGS. 2-4. In certain embodiments, the body 12 may form a notch 12_{N} at a corner thereof that indicates alignment and/or polarity information for proper mounting orientations of the LED package 42.

FIG. 6C is a bottom view of the LED package 42 of FIG. 6B. As illustrated, each of the leads 14-1 to 14-2 are arranged to exit the body 12 along the opposing side faces 12_{S} and be accessible from the mounting surface 42_{M} of the LED package 42. FIG. 6D is an end view of the LED package 42 of FIG. 6B along a short side or width of the LED package 42. As illustrated, the leads 14-1 and 14-4 extend from or exit the body from the opposing side faces 12_{S}. The leads 14-1 and 14-4 may further bend around a side step of the side faces 12_{S} and along a bottom face 12″ of the body to be accessible from the overall mounting surface 42, of the LED package 42. FIG. 6E is a side view of the LED package 42 of FIG. 6B along a long side or length of the LED package 42. From this view, the leads 14-1 to 14-3 are visible extending from a same side face 12s.

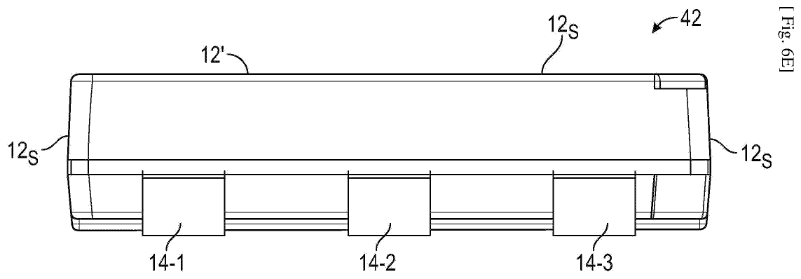

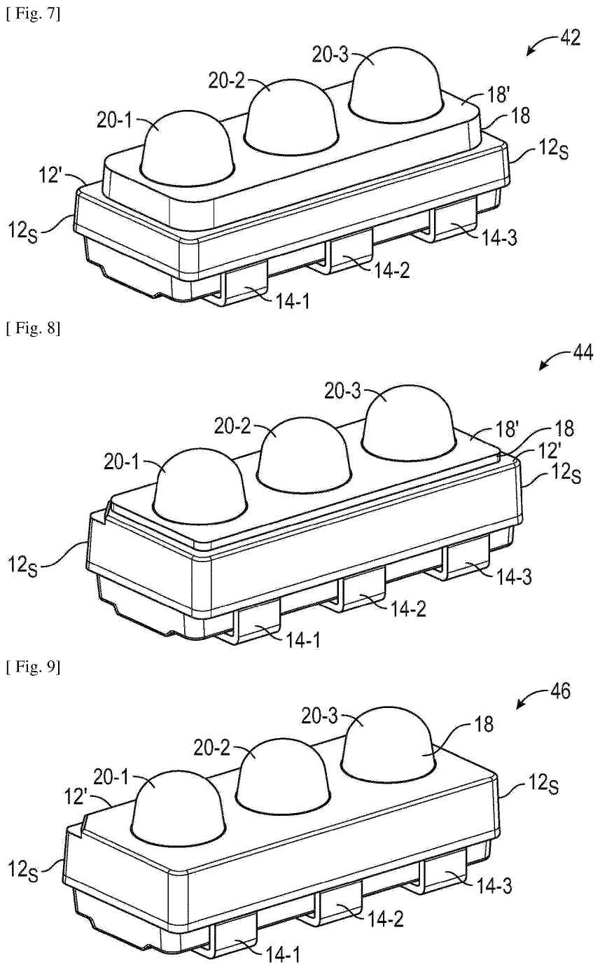

FIG. 7 is the top perspective view of the LED package 42 of FIG. 6A with the addition of the encapsulant 18 along the top face 12′ of the body 12. As previously described, the encapsulant 18 may fill and thereby encapsulate each of the cavities (e.g., 16-1 to 16-3 of FIG. 6B) and the LED chips that are mounted therein. The encapsulant 18 forms the plurality of lenses 20-1 to 20-3 such that a separate lens 20-1 to 20-3 is registered with a separate one of the cavities 16-1 to 16-3. In this manner, the plurality of lenses 20-1 to 20-3 are configured to focus, alter, or otherwise tailor the emission pattern of light generated by each of the LED chips. In certain embodiments, the lenses 20-1 to 20-3 form a shape that is circular, although other shapes are contemplated depending on the desired emission pattern. Some examples of alternative shapes include oval, ellipsoid bullet, flat, hex-shaped, and square. In certain embodiments, the encapsulant 18 forms the flash portion 18′ that is continuous between each of the lenses 20-1 to 20-3. By having the top face 12′ be continuously planar between the opposing side faces 12_{S}, added flexibility in the shape of the encapsulant 18, the lenses 20-1 to 20-3 and flash portion are provided. In FIG. 7, a thickness of the flash portion 18′ is in a range from 0.1 millimeters (mm) to 0.5 mm or more. In such embodiments, the thickness of the flash portion 18′ may elevate the lenses 20-1 to 20-3 a desired distance above the underlying LED chips to tailor emission patterns. In certain embodiments, the flash portion 18′ may extend along the top face 12′ to be within 1 mm of one or more of the side faces 12_{S} of the body. In this manner, harmful moisture ingress would have a longer distance to travel to reach the LED chips and/or lead frames within the cavities.

FIG. 8 is a top perspective view of an LED package 44 that is similar to the LED package 42 of FIG. 7 with a reduced thickness flash portion 18′ of the encapsulant 18. As illustrated, the flash portion 18′ is thinner than the example of FIG. 7. In certain embodiments, a thickness of the flash portion 18′ is in a range from 0.1 mm up to about 0.5 mm while still being less than the arrangement illustrated in FIG. 7. Such reduction in thickness is possible with the top face 12′ of the body 12 being continuously planar between opposing side faces 12_{S}. In certain embodiments, the flash portion 18′ may extend along the top face 12′ to be within 1 mm of one or more of the side faces 12_{S} of the body. In this manner, harmful moisture ingress would have a longer distance to travel to reach the LED chips and/or lead frames within the cavities.

FIG. 9 is a top perspective view of an LED package 46 that is similar to the LED package 44 of FIG. 8 except the flash portion 18′ of FIG. 8 is omitted. In this manner, the encapsulant 18 forms discrete lenses 20-1 to 20-3 that are separated by portions of the top face 12′ of the body 12. The lenses 20-1 to 20-3 may entirely cover the underlying cavities such that portions of each lens 20-1 to 20-3 extends along a portion of the top face 12′ outside the cavities. In certain embodiments, removing the flash portion 18′ of FIG. 8 may eliminate corners or other sharp surfaces of the encapsulant 18 that could otherwise impact light emissions in an undesired direction. In this manner, omitting the flash portion 18′ may provide substantially curved boundaries of the encapsulant 18 along the top face 12′. Additionally, omitting the flash portion 18′ may also provide enhanced contrast for the LED package 46 by leaving more surface area of the top face 12′ uncovered, particularly for embodiments where the body 12 is formed of a dark or even black material.

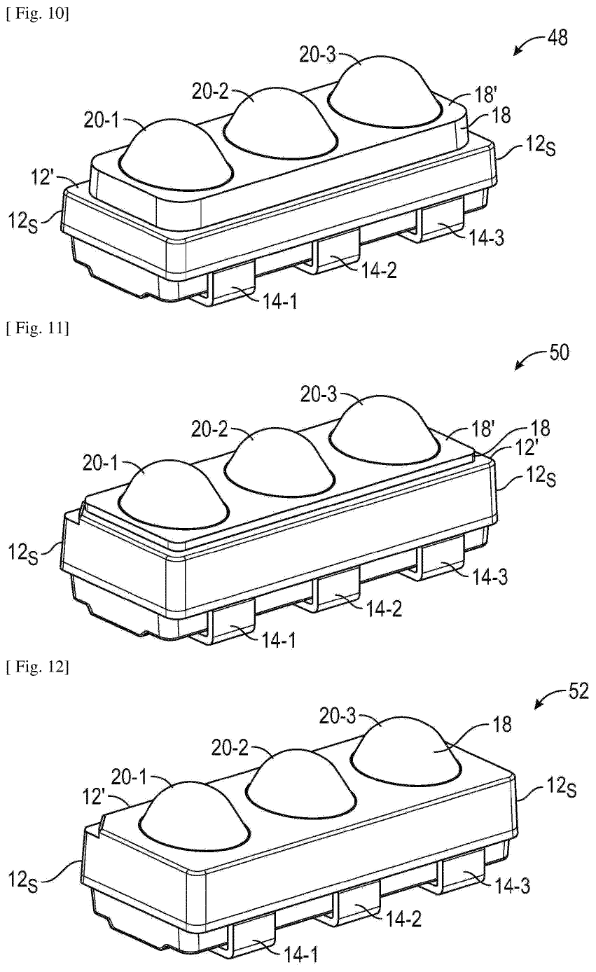

FIG. 10 is a top perspective view of an LED package 48 that is similar to the LED package 42 of FIG. 7 with lens shapes similar to the LED package 10 as illustrated in FIGS. 1B and 1F. For example, one or more of the lenses 20-1 to 20-3 may have a lens shape with no more than one line of symmetry when viewed at an angle perpendicular to the top face 12′. Accordingly, one or more of the lenses 20-1 to 20-3 may be formed with a shape where a focal point of the lens 20-1 to 20-3 is offset from a center of the underlying cavities (e.g., 16-1 to 16-3 of FIG. 1 C) to direct light in desired emission directions. For example, when the LED package 48 is arranged for use with an orientation where the lenses 20-1 to 20-3 are vertically aligned, the lens shapes may be arranged to direct highest intensity emissions downward. In still further embodiments, the underlying cavities (e.g., 16-1 to 16-3 of FIG. 1C) may be provided with cavity shapes as previously described for FIGS. 1C to 1E. In still further embodiments, LED chip positions for the LED package 48 may be arranged as previously described for any of FIGS. 1C to 1D and FIGS. 2 to 4.

FIG. 11 is a top perspective view of an LED package 50 that is similar to the LED package 48 of FIG. 10 with the flash portion 18′ similar to the LED package 44 of FIG. 8. Accordingly, the lens shapes may be implemented in combination with the thinner flash portions 18′ described above. As with other embodiments, the underlying cavities (e.g., 16-1 to 16-3 of FIG. 1C) may be provided with cavity shapes as previously described for FIGS. 1C to 1E and/or LED chip positions for the LED package 50 may be arranged as previously described for any of FIGS. 1C to 1D and FIGS. 2 to 4.

FIG. 12 is a top perspective view of an LED package 52 that is similar to the LED package 50 of FIG. 11 with the flash portion 18′ of FIG. 11 omitted in a similar manner to the LED package 46 of FIG. 9. Accordingly, the lens shapes may be implemented as discrete shapes along the top face 12′ of the body 12 as described above. As with other embodiments, the underlying cavities (e.g., 16-1 to 16-3 of FIG. 1C) may be provided with cavity shapes as previously described for FIGS. 1C to 1E and/or LED chip positions for the LED package 50 may be arranged as previously described for any of FIGS. 1C to 1D and FIGS. 2 to 4.

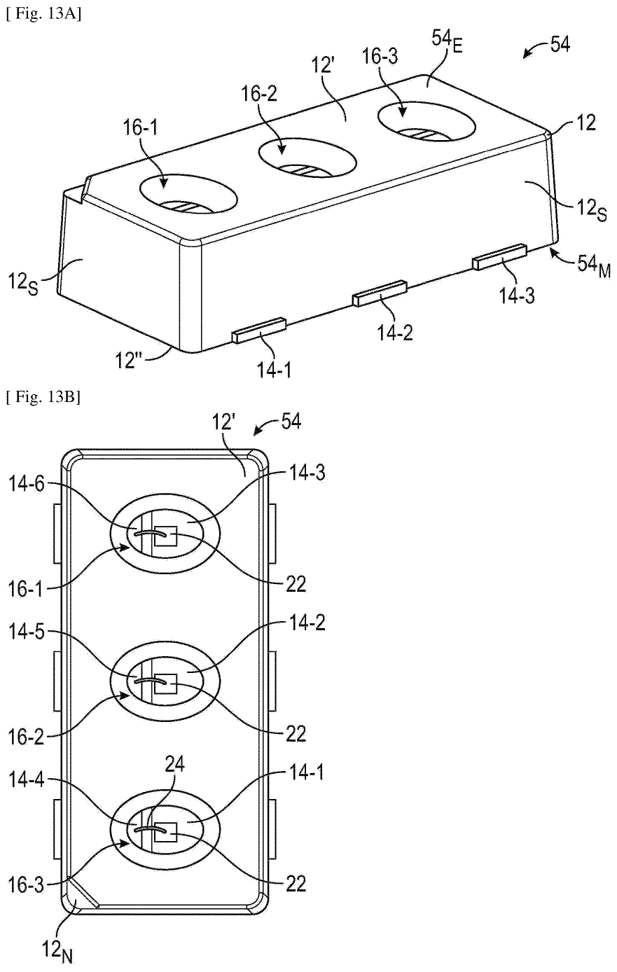

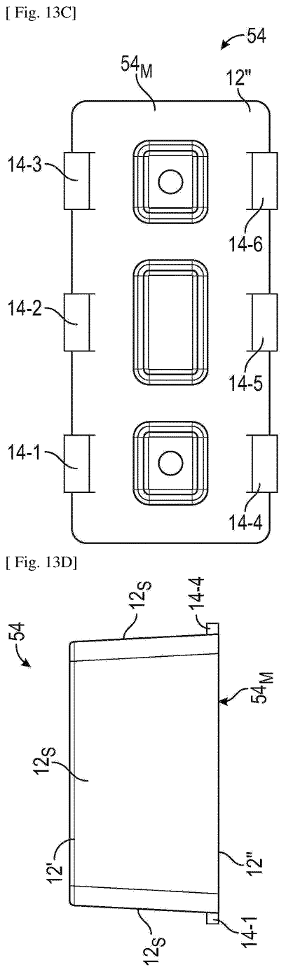

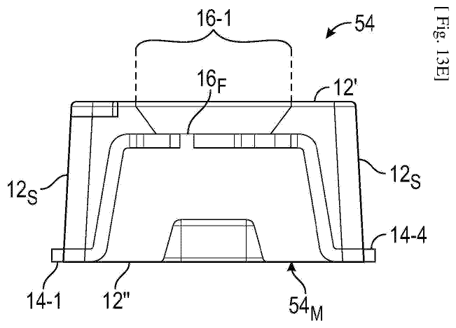

FIG. 13A is a top perspective view of an LED package 54 that is similar to the LED package 42 of FIG. 6A for embodiments where the side faces 12_{S} are continuously planar from the top face 12′ to the bottom face 12″ of the body 12. FIG. 13B is a top view of the LED package 54 of FIG. 13A with the addition of the LED chip 22 within each of the cavities 16-1 to 16-3. FIG. 13C is a bottom view of the LED package 54 of FIG. 13B. FIG. 13D is an end view of the LED package 54 of FIG. 13B along a short side or width of the LED package 54. In certain embodiments, the side faces 12_{S} may angle inward from the bottom face 12″ to the top face 12′ to allow room for potting material when closely arranged with other LED packages. FIG. 13E is an end view of the LED package 54 of FIG. 13B that is similar to FIG. 13D with the body 12 represented as semi-transparent. In this manner, the leads 14-1 and 14-4 and the cavity 16-1 are visible. As illustrated, portions of the leads 14-1 and 14-4 are accessible at the cavity floor 16_{F} while other portions of the leads 14-1 and 14-4 bend twice within the body 12 before exiting the side faces 12_{S} at positions proximate the mounting surface 54_{M}. In certain embodiments, bottom surfaces of the leads 14-1 and 14-4 that exit the body 12 are coplanar with the bottom face 12″. By positioning the leads 14-1 and 14-4 to exit the package proximate the mounting surface 54_{M}, an increased resistance to moisture ingress may be provided. For example, moisture that may follow the leads 14-1 and 14-4 from exposure outside the body 12 will have at least two bends and a large distance to travel within the body 12 before ever reaching the cavity 16-1.

FIG. 13F is a side view of the LED package 54 of FIG. 13B along a long side or length of the LED package 54. As illustrated, the side faces 12_{S} of the LED package 54 of FIGS. 13A to 13E do not include the side steps described above for the LED package 42 of FIGS. 6A to 6F that accommodate bends in the lead 14-1 to 14-6. By having the side faces 12_{S} continuously planar from the top face 12′ to the bottom face 12″, the leads 14-1 to 14-6 may be arranged to extend or protrude from portions of the side faces 12_{S} that are closer to the bottom face 12″. As best illustrated in FIGS. 13D and 13E, bottom faces of the leads 14-1 to 14-6 may be coplanar with the bottom face 12″ of the body 12. By positioning the protruding portions of the leads 14-1 to 14-6 along the side faces 12_{S} farther from the cavities 16-1 to 16-3, larger distances are provided for harmful moisture ingress to travel before reaching the LED chips 22 and adversely impacting operation of the LED package 54. Accordingly, the LED package 54 may exhibit improved reliability. Additionally, the continuously planar side faces 12_{S} may also require less amounts of potting material for coverage when the LED package is mounted for operation, thereby saving manufacturing costs.

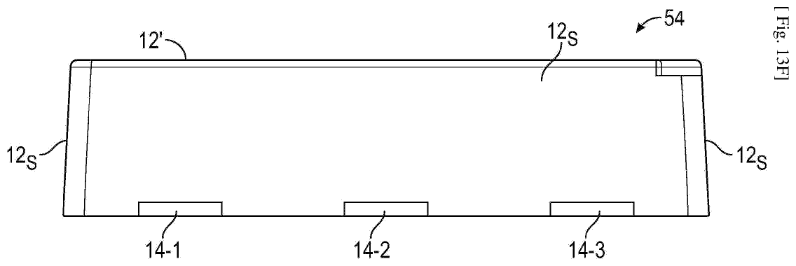

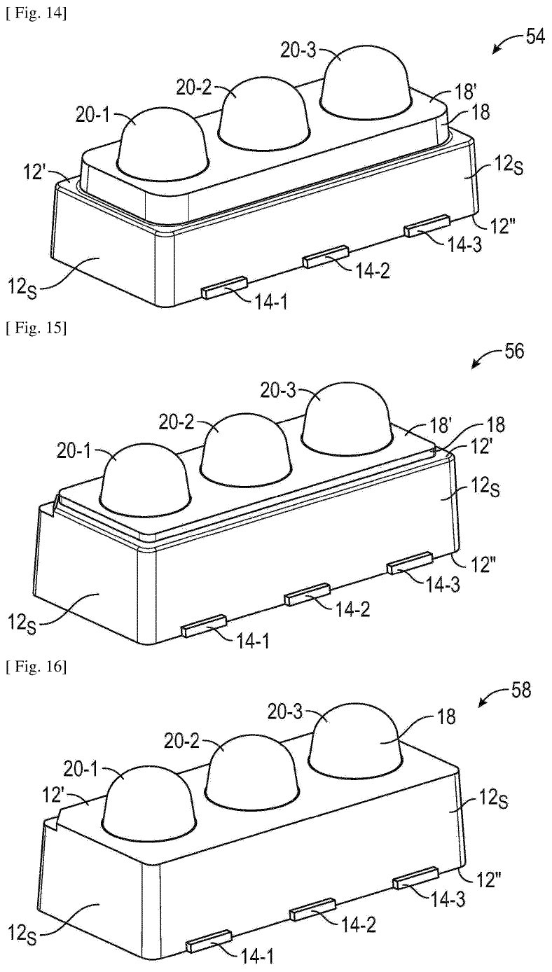

FIGS. 14 to 19 are top perspective views of LED packages similar to the LED package 54 of FIGS. 13A to 13E with arrangements of encapsulants and lenses similar to the embodiments illustrated in FIGS. 7 to 12. The descriptions of the encapsulant 18, the lenses 20-1 to 20-3, and the flash portions 18′ provided above for FIGS. 7 to 12 may respectively be applied to FIGS. 14 to 19 in the context of LED packages with side faces 12_{S} that are continuously planar from top faces 12′ to bottom faces 12″. For any of the embodiments described below for FIGS. 14 to 19, the underlying cavities (e.g., 16-1 to 16-3 of FIG. 1C) may be provided with cavity shapes as previously described for FIGS. 1C to 1E and/or LED chip positions for the LED package 50 may be arranged as previously described for any of FIGS. 1C to 1D and FIGS. 2 to 4.

FIG. 14 is a top perspective view of the LED package 54 of FIG. 13A with the addition of the encapsulant 18 along the top face 12′ of the body 12. In FIG. 14, the thickness of the flash portion 18′ of the encapsulant 18 is in a range as described above for FIG. 7, thereby positioning the lenses 20-1 to 20-3 at a desired distance above the underlying LED chips to tailor emission patterns thereof. Such arrangements may be implemented in combination with the continuously planar side faces 12_{S}.

FIG. 15 is a top perspective view of an LED package 56 that is similar to the LED package 54 of FIG. 14 with the reduced thickness flash portion 18′ of the encapsulant 18. In this regard, the flash portion 18′ of the LED package 56 may be formed with a reduced thickness in a similar manner to the flash portion 18′ of the LED package 44 of FIG. 8 in combination with the continuously planar side faces 12_{S}.

FIG. 16 is a top perspective view of an LED package 58 that is similar to the LED package 56 of FIG. 15 except the flash portion 18′ of FIG. 15 is omitted. In this regard, arrangement of the encapsulant 18 and the discrete lenses 20-1 to 20-3 is provided in a similar manner to the LED package 46 of FIG. 9 in combination with the continuously planar side faces 12_{S}. As with FIG. 9, the lenses 20-1 to 20-3 of FIG. 16 may entirely cover the underlying cavities such that portions of each lens 20-1 to 20-3 extend along a portion of the top face 12′ outside the cavities.

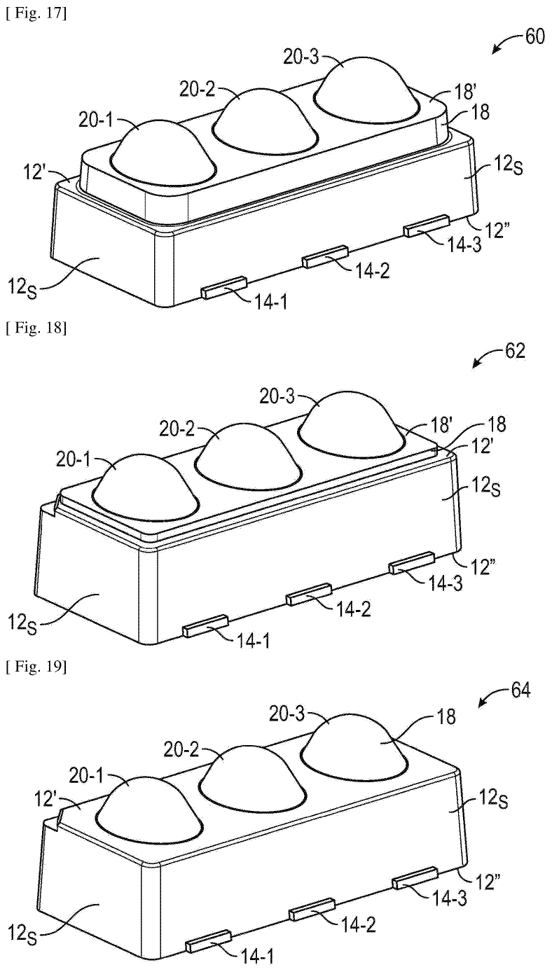

FIG. 17 is a top perspective view of an LED package 60 that is similar to the LED package 54 of FIG. 14 with lens shapes similar to the LED package 48 of FIG. 10. For example, one or more of the lenses 20-1 to 20-3 may have a lens shape with no more than one line of symmetry when viewed at an angle perpendicular to the top face 12′. Accordingly, one or more of the lenses 20-1 to 20-3 may be formed with a shape where a focal point of the lens 20-1 to 20-3 is offset from a center of the underlying cavities (e.g., 16-1 to 16-3 of FIG. 1 C) to direct light with highest emission intensities in desired emission directions that are offset from center. Such arrangements may be implemented in combination with the continuously planar side faces 12_{S}.

FIG. 18 is a top perspective view of an LED package 62 that is similar to the LED package 60 of FIG. 17 with the flash portion 18′ similar to the LED package 56 of FIG. 15. As previously described, the lens shapes for offset emissions of highest intensity may be implemented with the thinner flash portion 18′ along the top face 12′ of the body 12. Accordingly, the thinner flash portion 18′ and lenses 20-1 to 20-3 of FIG. 18 may be implemented in combination with the continuously planar side faces 12_{S}.

FIG. 19 is a top perspective view of an LED package 64 that is similar to the LED package 62 of FIG. 18 except the flash portion 18′ of FIG. 18 is omitted. In this regard, arrangement of the encapsulant 18 and discrete lenses 20-1 to 20-3 is provided in a similar manner to the LED package 46 of FIG. 9 in combination with the continuously planar side faces 12_{S} of FIG. 19. As with FIG. 9, the lenses 20-1 to 20-3 of FIG. 19 may entirely cover the underlying cavities such that portions of each lens 20-1 to 20-3 extend along a portion of the top face 12′ outside the cavities.

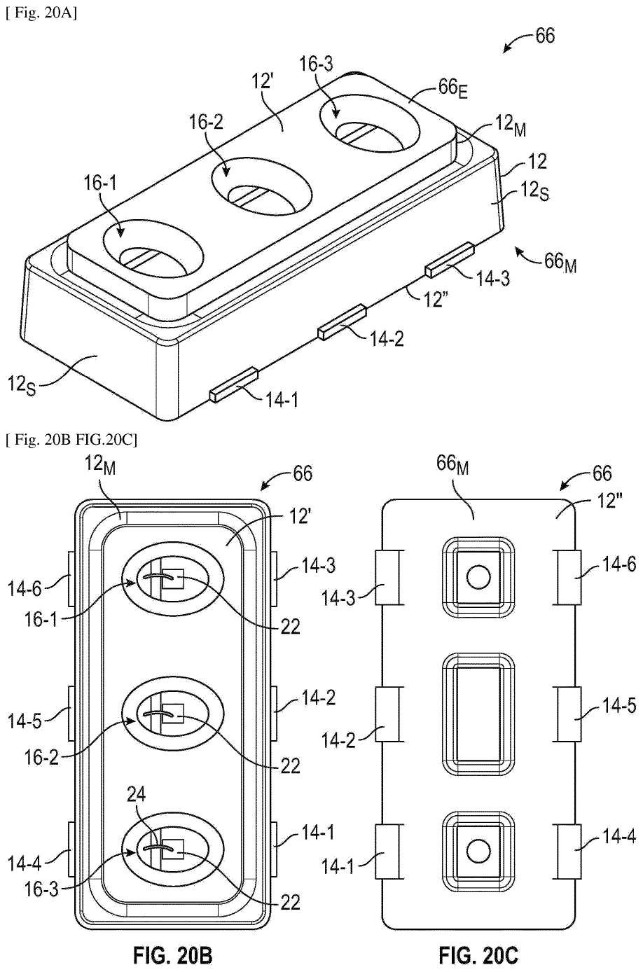

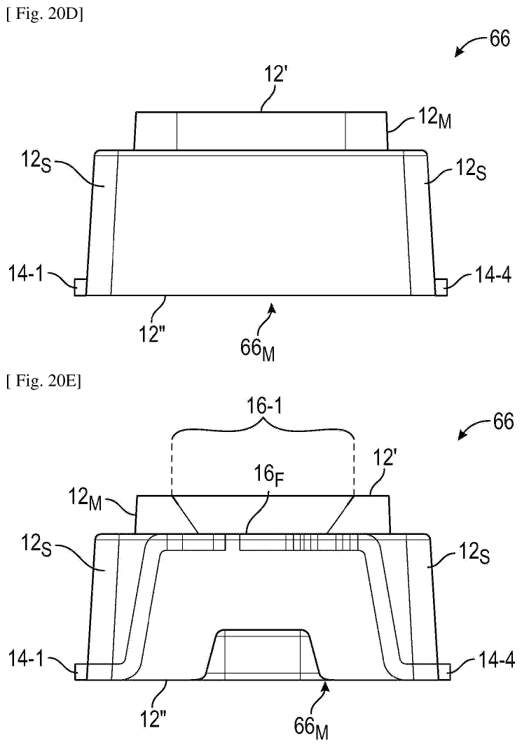

FIG. 20A is a top perspective view of an LED package 66 that is similar to the LED package 54 of FIGS. 13A to 13F and further includes the body mesa 12_{M} of the LED package 10 of FIGS. 1A to 1 F. FIG. 20B is a top view of the LED package 66 of FIG. 20A with the addition of the LED chip 22 within each of the cavities 16-1 to 16-3. FIG. 20C is a bottom view of the LED package 66 of FIG. 20B. FIG. 20D is an end view of the LED package 66 of FIG. 20B along a short side or width of the LED package 66. FIG. 20E is an end view of the LED package 66 of FIG. 20B that is similar to FIG. 20D with the body 12 represented as semi-transparent. The general description of the LED package 66 of FIGS. 20A to 20E corresponds to the description of the LED package 54 of FIGS. 13A to 13F while the description of the body mesa 12_{M} corresponds to the description provided in the context of the LED package 10 of FIGS. 1A to 1 F. Additionally, the LED package 66 may further include the encapsulant 18 and the lenses 20-1 to 20-3 described above for any of FIG. 1 B, 1 F, 14, 16, 17, or 19. The presence of the body mesa 12_{M} may provide increased surface area for bonding with the encapsulant 18 described above and/or provide increased distance moisture ingress has to travel along the top face 12′ before reaching the cavities 16-1 to 16-3.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

1. A light-emitting diode (LED) package comprising:
a body forming a plurality of cavities, a first cavity of the plurality of cavities forming a first cavity shape with no more than one line of symmetry;
a plurality of LED chips, wherein each cavity of the plurality of cavities comprises at least one LED chip of the plurality of LED chips; and
a plurality of lenses on the body, a first lens of the plurality of lenses being registered with the first cavity, and the first lens forming a first lens shape with no more than one line of symmetry.

2. The LED package of claim 1, wherein the first cavity comprises a sidewall that is arranged around a perimeter of the at least one LED chip within the first cavity, the sidewall forming a first sidewall portion and a second sidewall portion positioned on opposite sides of the at least one LED chip, wherein the second sidewall portion comprises a larger surface area of the cavity than the first sidewall portion.

3. The LED package of claim 2, wherein:
the at least one LED chip is mounted at a cavity floor of the first cavity;
a first angle is formed from the first sidewall portion relative to a perpendicular line from the cavity floor;
a second angle is formed between the second sidewall portion relative to
the perpendicular line from the cavity floor; and
the first angle is less than the second angle.

4. The LED package of claim 3, wherein the first angle is in a range from 5 degrees to 25 degrees and the second angle is in a range from 25 degrees to 50 degrees.

5. The LED package of claim 3, wherein the first angle is in a range from 10 degrees to 20 degrees and the second angle is in a range from 30 degrees to 40 degrees.

6. The LED package of claim 2, wherein the sidewall is continuously curved around the perimeter of the at least one LED chip.

7. The LED package of claim 1, wherein each cavity of the plurality of cavities comprises a cavity shape that is the same as the first cavity shape, and each lens of the plurality of lenses comprises a lens shape that is the same as the first lens shape.

8. The LED package of claim 1, wherein:
the body forms a rectangular shape with a long side and a short side;
the plurality of cavities are arranged in a linear manner in a direction corresponding to the long side; and
the first cavity forms a single line of symmetry that is oriented parallel to the long side.

9. The LED package of claim 1, wherein the plurality of cavities further comprises a second cavity forming a second cavity shape with no more than one line of symmetry and a third cavity forming a third cavity shape with no more than one line of symmetry.

10. The LED package of claim 1, further comprising a lead frame structure at least partially within the body and electrically coupled to the plurality of LED chips.

11. The LED package of claim 1, wherein:
the body comprises a top face, a bottom face, and side faces that bound the top face and the bottom face;
the plurality of cavities are in the top face of the body; and
the top face is continuously planar between opposing side faces.

12. The LED package of claim 11, wherein the side faces are continuously planar between the top face and the bottom face.

13. A light-emitting diode (LED) package comprising:
a first LED chip and a second LED chip; and
a body comprising:
a first cavity with a first cavity floor on which the first LED chip resides and a first sidewall that extends between a surface of the body and the first cavity floor, wherein an angle of the first sidewall relative to the first cavity floor varies around a perimeter of the first LED chip; and
a second cavity with a second cavity floor on which the second LED chip resides and a second sidewall that extends between the surface of the body and the second cavity floor, wherein an angle of the second sidewall relative to the second cavity floor varies around a perimeter of the second LED chip.

14. The LED package of claim 13, wherein:
the angle of the first sidewall is in a range from 5 degrees to 25 degrees on one side of the first LED chip and in a range from 25 degrees to 50 degrees on an opposing side of the first LED chip; and
the angle of the second sidewall is in a range from 5 degrees to 25 degrees on one side of the second LED chip and in a range from 25 degrees to 50 degrees on an opposing side of the second LED chip.

15. The LED package of claim 13, wherein:
the angle of the first sidewall is in a range from 10 degrees to 20 degrees on one side of the first LED chip and in a range from 30 degrees to 40 degrees on an opposing side of the first LED chip; and
the angle of the second sidewall is in a range from 10 degrees to 20 degrees on one side of the second LED chip and in a range from 30 degrees to 40 degrees on an opposing side of the second LED chip.

16. The LED package of claim 13, further comprising a lead frame structure at least partially within the body and electrically coupled to the first LED chip and the second LED chip.

17. The LED package of claim 13, further comprising a first lens that is registered with the first cavity and a second lens that is registered with the second cavity, wherein each of the first lens and the second lens forms a shape with no more than one line of symmetry.

18. The LED package of claim 13, further comprising a third LED chip and a third cavity with a third cavity floor on which the third LED chip resides and a third sidewall that extends between the surface of the body and the third cavity floor, wherein an angle of the third sidewall relative to the third cavity floor varies around a perimeter of the third LED chip.

19. The LED package of claim 13, wherein the first LED chip is positioned offset from a center point of the first cavity floor, and the second LED chip is positioned offset from a center point of the second cavity floor.

20. The LED package of claim 13, wherein the first LED chip is positioned offset from a center point of the first cavity floor, and the second LED chip is positioned at a center point of the second cavity floor.

21. The LED package of claim 13, wherein:
the body comprises a top face, a bottom face, and side faces that bound the top face and the bottom face;
the first cavity and the second cavity are in the top face of the body; and
the top face is continuously planar between opposing side faces.

22. The LED package of claim 21, wherein the side faces are continuously planar between the top face and the bottom face.
